(19) United States
(12) Patent Application Publication
(10) Pub. No.: US 2014/0056094 A1
(43) Pub. Date: Feb. 27, 2014

(54) WORD-LINE ACTIVATION CIRCUIT, SEMICONDUCTOR MEMORY DEVICE, AND SEMICONDUCTOR INTEGRATED CIRCUIT

(71) Applicant: PANASONIC CORPORATION, Osaka (JP)

(72) Inventors: Tadashi NITTA, Kyoto (JP); Tsuyoshi KOIKE, Shiga (JP)

(73) Assignee: PANASONIC CORPORATION, Osaka (JP)

(21) Appl. No.: 13/946,850

(22) Filed: Jul. 19, 2013

Related U.S. Application Data
(63) Continuation of application No. PCT/JP2012/000280, filed on Jan. 18, 2012.

(30) Foreign Application Priority Data
Feb. 22, 2011 (JP) 2011-036045

(51) Int. Cl. G11C 11/413; G11C 11/418

(52) U.S. Cl. CPC G11C 11/413; G11C 11/418
USPC 365/230.06

(57) ABSTRACT

In a state where a signal (IN) is at “H” and an NMOS transistor (403) is on, when a signal (PCLK) changes to “H” and a PMOS transistor (401) turns off, an output node (N1) becomes coupled to a word-line activation signal (WACTCLK) via the NMOS transistor (403). When the word-line activation signal (WACTCLK) changes to “L,” a word line signal (MWL) changes to “L.” Since the signal (PCLK) is at “H” and the NMOS transistor (405) is on, this NMOS transistor (405) can assist discharging of the word-line activation signal (WACTCLK) to a ground voltage.

### CROSS-REFERENCE TO RELATED APPLICATIONS

This is a continuation of International Application No. PCT/JP2012/000280 filed on Jan. 18, 2012, which claims priority to Japanese Patent Application No. 2011-036045 filed on Feb. 22, 2011. The entire disclosures of these applications are incorporated by reference herein.

### BACKGROUND

The present disclosure relates to semiconductor memory devices, and more particularly to a technique for high-speed operation of a word-line activation circuit that selects and activates word lines.

FIG. 15 illustrates an example of a circuit configuration including a word-line activation circuit of a semiconductor memory device shown in Japanese Patent Publication No. 2007-164922. In FIG. 15, decoders 10 serving as word-line activation circuits receive different address signals ADU0-3 and word-line activation signals WACTCLK[3:0], and activate different word lines WL[3:0]. The decoders 10 have similar configurations. Specifically, the decoder 10 for activating the word line WL[0] includes an inverter 14 that activates the word line WL[0], a PMOS transistor 12 that holds the potential at the word line WL[0], a PMOS transistor 11 that precharges the word line WL[0] based on the address signal ADU0, and an NMOS transistor 13 that turns on and off based on the address signal ADU0. The word-line activation signal WACTCLK[0] is input to the source of the NMOS transistor 13, and coupled to an intermediate signal MWL[0] for activating a word line via the NMOS transistor 13.

A word-line activation signal output circuit 25 includes two NMOS transistors 21 and 22 and an inverter 23. The word-line activation signal WACTCLK[0] is controlled by the NMOS transistors 21 and 22. The NMOS transistor 21 is activated in response to the address signal AD, and the NMOS transistor 22 is activated in response to an inverted signal of the address signal AD input via the inverter 23. The source of the NMOS transistor 21 is coupled to a power supply control circuit 24. The power supply control circuit 24 controls the “H” level of the word-line activation signal WACTCLK[0] to be lower than the power supply voltage. The other word-line activation signals WACTCLK[3:1] are also output from the word-line activation signal output circuits 25 having the same configuration and receiving address signals different from the address signal AD, and are individually selected based on the address signals.

FIG. 16 is a timing chart of input/output signals in the circuit configuration illustrated in FIG. 15. At an initial stage, the address signal AD is at “H,” and the word-line activation signal WACTCLK[0] is set at “H” that is lower than a power supply voltage by the power supply control circuit 24. On the other hand, since the address signal ADU0 is at “L,” the NMOS transistor 13 turns off, the PMOS transistor 11 turns on, the intermediate signal MWL[0] to be input to the inverter 14 is at “H,” and the word line WL[0] is at “L.”

When the address signal ADU0 changes from “L” to “H,” the NMOS transistor 13 turns on and the PMOS transistor 11 turns off. On the other hand, when the address signal AD changes from “H” to “L,” the word-line activation signal WACTCLK[0] changes to “L,” the intermediate signal MWL[0] changes to “L,” and the word line WL[0] changes to “H.”

Then, a change of the address signal ADU0 from “H” to “L” causes the intermediate signal MWL[0] to change to “H,” and the word line WL[0] to be precharged to “L.” In addition, a change of the address signal AD from “L” to “H” causes the word-line activation signal WACTCLK[0] to change to “H” that is lower than the power supply voltage.

As described above, the word lines WL[3:0] are activated based on the amplitudes of the word-line activation signals WACTCLK[3:0], and these amplitudes are reduced by reducing the “H” levels of the word-line activation signals WACTCLK[3:0] by means of the power supply control circuit 24. In this manner, the word lines WL[3:0] can be activated at high speed. Setting the “H” level below the power supply voltage achieves lower power consumption of a semiconductor memory device.

### SUMMARY

In the configuration shown in Japanese Patent Publication No. 2007-164922, the “H” level of the word-line activation signal is lower than the power supply voltage and the amplitude thereof is reduced in order to achieve high-speed activation of word lines.

With increase in capacity of semiconductor memory devices, however, an increase in the number of word lines increases the number of word-line activation circuits coupled to one word-line activation signal and also increases the length of a line for the word-line activation signal. Accordingly, the load on the word-line activation signal increases, resulting in the problem of slow activation of the word lines due to a decrease in amplitude of the word-line activation signal. Slow activation of the word lines disadvantageously increases the possibility of failure in satisfying a required time (access time) until data is output.

There is also another problem that if the activation time of the word-line activation signal is extended in order to obtain a sufficient amplitude of the word-line activation signal for activating word lines even with a decrease in amplitude of the word-line activation signal, a required operating frequency (cycle time) cannot be satisfied.

It is therefore an object of the present disclosure to provide a word-line activation circuit capable of activating word lines at high speed even with, for example, an increase in a load on a word-line activation signal in a semiconductor memory device requiring large capacity and high-speed operation.

In a first aspect of the present disclosure, a word-line activation circuit includes: an output node configured to output a word line signal; a first transistor of a first conductivity type configured to receive a word-line activation signal at a source thereof, have its drain coupled to the output node, and receive a first input signal at a gate thereof; a second transistor of a second conductivity type configured to have its source coupled to a first power supply, have its drain coupled to the output node, and receive a second input signal at a gate thereof; and a third transistor of the first conductivity type configured to have its source coupled to a second power supply, have its drain coupled to the source of the first transistor, and receive the second input signal at a gate thereof.

In the first aspect, in a state where the first input signal is at a first logic level (e.g., “H”) and the first transistor is on, when the second input signal changes to the first logic level to cause the second transistor to turn off, the output node becomes coupled to the word-line activation signal via the first transistor. In this state, a change of the word-line activation signal to a second logic level (e.g., “L”) causes the word line signal to change to the second logic level. At this time, since the second input signal is at the first logic level so that the third transistor is on, this third transistor can assist a change of the word-line activation signal to the second logic level (e.g., discharging to the ground voltage). Accordingly, a decrease in signal amplitude and a signal delay associated therewith caused by a load on the word-line activation signal can be reduced. As a result, the word lines can be activated at higher speed, thereby shortening the time (access time) until data is output.

The word-line activation circuit of the first aspect may further include a fourth transistor of the second conductivity type configured to have its source coupled to the first power supply, have its drain coupled to the drain of the third transistor, and receive the second input signal at a gate thereof.

In this configuration, when the word line signal changes to the second logic level and then the second input signal changes to the second logic level, the third transistor turns off and the fourth transistor turns on. In this state, when the word-line activation signal returns to the first logic level, the fourth transistor can assist the returning of the word-line activation signal to the first logic level (e.g., precharging to the power supply voltage). As a result, the time (cycle time) until next operation starts can be shortened.

In a second aspect of the present disclosure, a word-line activation circuit includes: an output node configured to output a word line signal; a first transistor of a first conductivity type configured to receive a word-line activation signal at a source thereof, have its drain coupled to the output node, and receive a first input signal at a gate thereof; a second transistor of a second conductivity type configured to have its source coupled to a first power supply, have its drain coupled to the output node, and receive a second input signal at a gate thereof; a third transistor of the first conductivity type configured to have its source coupled to a second power supply and have its drain coupled to the source of the first transistor; and a fourth transistor of the second conductivity type configured to have its source coupled to the first power supply, have its drain coupled to the gate of the third transistor, and have its gate coupled to the source of the first transistor.

In the second aspect, in a state where the first input signal is at a first logic level (e.g., “H”) and the first transistor is on, when the second input signal changes to the first logic level to cause the second transistor to turn off, the output node becomes coupled to the word-line activation signal via the first transistor. In this state, a change of the word-line activation signal to a second logic level (e.g., “L”) causes the word line signal to change to the second logic level. At this time, since the word-line activation signal is at the second logic level, the fourth transistor turns on, and thus, the voltage of the first power supply is applied to the gate of the third transistor, thereby causing the third transistor to turn on. Thus, the third transistor can assist a change of the word-line activation signal to the second logic level (e.g., discharging to the ground voltage). Accordingly, a decrease in signal amplitude and a signal delay associated therewith caused by a load on the word-line activation signal can be reduced. As a result, the word lines can be activated at higher speed, thereby shortening the time (access time) until data is output.

In a third aspect, a semiconductor memory device includes a word-line activation circuit block including a predetermined number of the word-line activation circuits of the first or second aspect; and a word-line activation signal output block configured to receive a part of an address signal and a clock signal for controlling a word-line activation timing, generate and output, to each of the predetermined number of word-line activation circuits, either the word-line activation signal or an inverted signal of the word-line activation signal and either the second input signal or an inverted signal of the second input signal.

Preferably, in the semiconductor memory device of the third aspect, the word-line activation circuit block comprises a plurality of word-line activation circuit blocks, the semiconductor memory device further includes at least one address decoder configured to receive a remain other than the part of the address signal and generate an address decode signal for selecting one of the word-line activation circuit blocks, and each of the word-line activation circuit blocks is configured such that the predetermined number of word-line activation circuit blocks receive a common signal as the first input signal, and when one of the word-line activation circuit blocks is selected based on the address decode signal, the first input signal to be input to the selected word-line activation circuit block becomes active.

The circuit configurations of the word-line activation circuits of the first and second aspect may be used for a semiconductor integrated circuit in which a pulse signal is activated based on a pulse activation signal. In this case, the third transistor can also assist a change of the pulse activation signal to the second logic level (e.g., discharging to the ground voltage). Accordingly, a decrease in signal amplitude and a signal delay associated therewith caused by a load on the pulse activation signal can be reduced. As a result, the pulse signal can rise at higher speed, thereby accelerating activation of circuits at subsequent stages.

According to the present disclosure, a change of a word-line activation signal can be assisted by a transistor in a word-line activation circuit, thereby reducing a decrease in signal amplitude and a signal delay associated therewith caused by a load on the word-line activation signal. As a result, word lines can be activated at high speed, thereby shortening the access time.

In addition, according to the present disclosure, a change of a pulse activation signal can be assisted by a transistor in a semiconductor integrated circuit, thereby reducing a decrease in signal amplitude and a signal delay associated therewith caused by a load on the pulse activation signal. As a result, pulse signals can be activated at high speed, thereby accelerating activation of circuits at subsequent stages.

### BRIEF DESCRIPTION OF THE DRAWINGS

FIG. 1 is a block diagram schematically illustrating a semiconductor memory device according to an embodiment.

FIG. 2 illustrates a circuit configuration of a row decoder control circuit according to a first embodiment.

FIG. 3 illustrates a circuit configuration of a row decoder according to the first embodiment.

FIG. 4 illustrates a circuit configuration of a word-line activation circuit according to the first embodiment.

FIG. 5 is a timing chart showing operation in word-line activation in the first embodiment.

FIG. 6 illustrates a circuit configuration of a word-line activation circuit according to a second embodiment.

FIG. 7 is a timing chart showing operation in word-line activation in the second embodiment.

FIG. 8 illustrates a variation of the circuit configuration of the word-line activation circuit of the second embodiment.

FIG. 9 illustrates a circuit configuration of a row decoder control circuit according to a third embodiment.

FIG. 10 illustrates a circuit configuration of a word-line activation circuit according to the third embodiment.

FIG. 11 is a timing chart showing operation in word-line activation in the third embodiment.

FIG. 12 illustrates a circuit configuration of a variation of the word-line activation circuit.

FIG. 13 illustrates a circuit configuration of a variation of the word-line activation circuit.

FIG. 14 illustrates a circuit configuration of a variation of the word-line activation circuit.

FIG. 15 illustrates an example of a circuit configuration including a conventional word-line activation circuit.

FIG. 16 is a timing chart showing operation in word-line activation in the circuit configuration illustrated in FIG. 15.

### DETAILED DESCRIPTION

Embodiments of the present disclosure will be described with reference to the drawings.

### First Embodiment

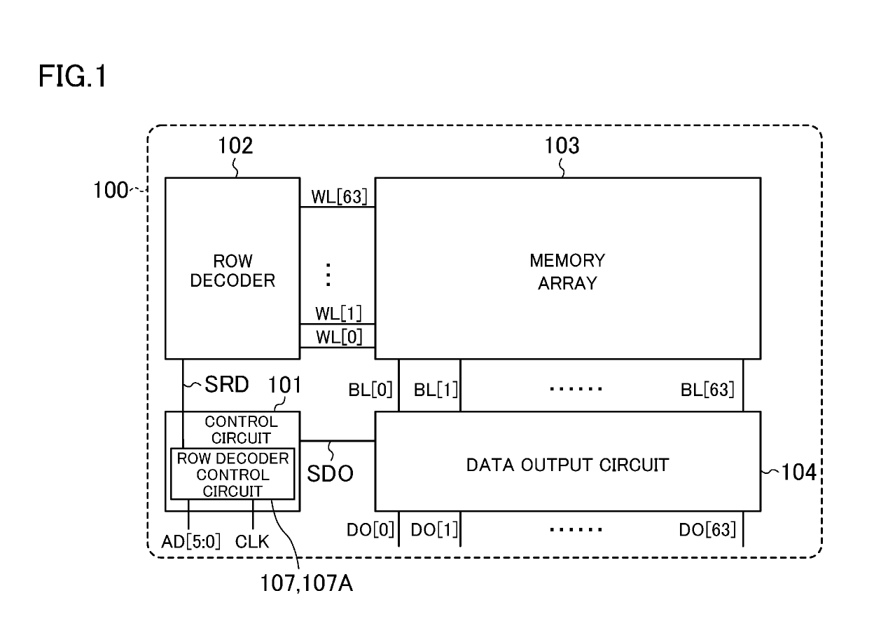

FIG. 1 is a block diagram schematically illustrating a semiconductor memory device according to a first embodiment. In FIG. 1, a semiconductor memory device 100 includes a memory array 103, a row decoder 102 that activates word lines WL[63:0] of the memory array 103, a data output circuit 104 that receives data from the memory array 103 through bit lines BL[63:0], and a control circuit 101 that controls the row decoder 102 and the data output circuit 104.

The control circuit 101 includes a row decoder control circuit 107 that receives address signals AD[5:0] and a clock signal CLK and generates a row decoder control signal SRD. The row decoder control signal SRD is sent to the row decoder 102. The control circuit 101 outputs a data output circuit control signal SDO to the data output circuit 104.

The row decoder 102 receives the row decoder control signal SRD from the control circuit 101, and selects and activates one of the word lines WL[63:0]. Based on the activated one of the word lines WL[63:0], the memory array 103 outputs memory cell data from the bit lines BL[63:0]. Based on the memory cell data output from the bit lines BL[63:0] and the data output circuit control signal SDO from the control circuit 101, the data output circuit 104 generates and outputs output data DO[63:0].

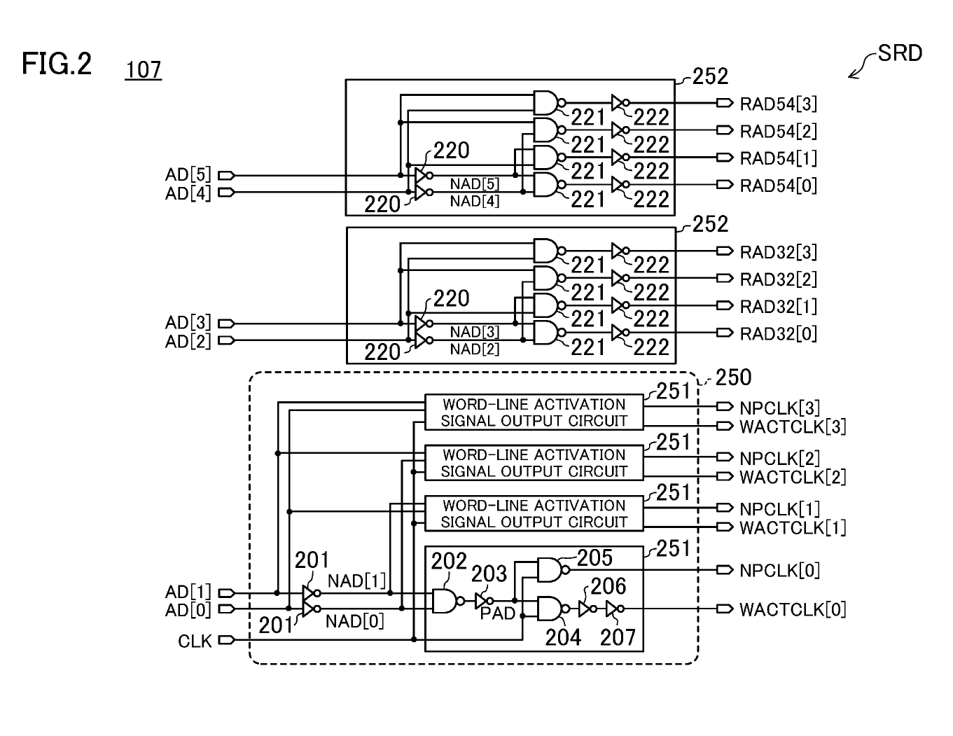

FIG. 2 illustrates a circuit configuration of the row decoder control circuit 107 of this embodiment. The row decoder control circuit 107 illustrated in FIG. 2 includes a word-line activation signal output block 250 and two address decoders 252, and generates, as row decoder control signals SRD, address decode signals RAD32[3:0] and RAD54[3:0], inverted word-line precharge signals NPCLK[3:0] for precharging the potentials of the word lines, and word-line activation signals WACTCLK[3:0] for controlling activation timings of the word lines.

Each of the address decoders 252 includes two inverters 220, four NAND logic devices 221, and four inverters 222, receives address signals AD[5:4] or AD[3:2], and outputs address decode signals RAD54[3:0] or RAD32[3:0]. The address decode signals RAD54[3:0] and RAD32[3:0] are used for selecting one of word-line activation circuit blocks 300, which will be described later. The inverters 220 receive the address signals AD[5:4] or AD[3:2], and output inverted address signals NAD[5:4] or NAD[3:2]. The four NAND logic devices 221 receive different combinations of one of the address signal AD[5] or the inverted address signal NAD[5] and one of the address signal AD[4] or the inverted address signal NAD[4] (or one of the address signal AD[3] or the inverted address signal NAD[3] and one of the address signal AD[2] or the inverted address signal NAD[2]). The four inverters 222 receive the outputs of the four NAND logic devices 221, and output inverted signals of these outputs as address decode signals RAD54[3:0] or RAD32[3:0].

The word-line activation signal output block 250 includes two inverters 201 and four word-line activation signal output circuits 251, receives address signals AD[1:0] and a clock signal CLK, and outputs word-line activation signals WACTCLK[3:0] and inverted word-line precharge signals NPCLK[3:0]. Instead of the word-line activation signals WACTCLK, inverted signals thereof may be output. Instead of the inverted word-line precharge signals NPCLK, word-line precharge signals PCLK[3:0] may be output. Each of the word-line activation signal output circuits 251 includes NAND logic devices 202, 204, and 205 and inverters 203, 206, and 207.

The two inverters 201 receive the address signals AD[1] and AD[0], and output the inverted address signals NAD[1] and NAD[0]. The four word-line activation signal output circuits 251 receive the clock signal CLK and different combinations of one of the address signal AD[1] or the inverted address signal NAD[1] and one of the address signal AD[0] or the inverted address signal NAD[0]. The four word-line activation signal output circuits 251 output the word-line activation signals WACTCLK[3:0] and the inverted word-line precharge signals NPCLK[3:0].

In each of the word-line activation signal output circuits 251, the NAND logic device 202 receives one of the address signal AD[1] or the inverted address signal NAD[1] and one of the address signal AD[0] or the inverted address signal NAD[0]. The inverter 203 receives an output of the NAND logic device 202, and outputs an inverted signal thereof as an address decode signal PAD. The NAND logic devices 204 and 205 respectively receive the clock signal CLK and the address decode signal PAD. An output of the NAND logic device 204 is output as one of the word-line activation signals WACTCLK[3:0] through the inverters 206 and 207. An output of the NAND logic device 205 is produced as one of the inverted word-line precharge signals NPCLK[3:0].

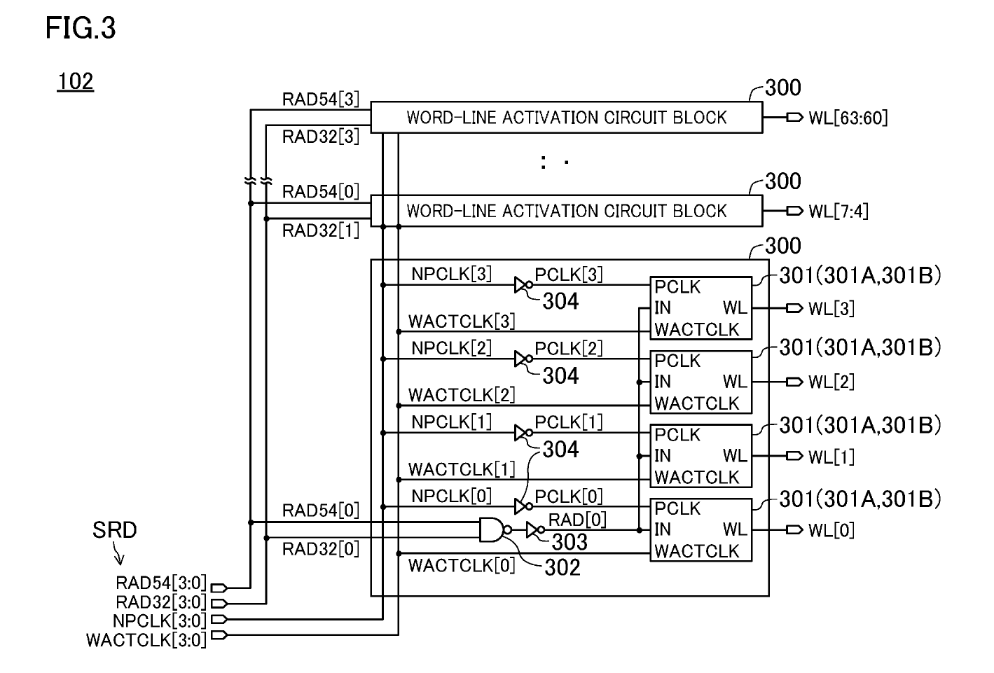

FIG. 3 illustrates a circuit configuration of the row decoder 102 of this embodiment. The row decoder 102 illustrated in FIG. 3 includes 16 word-line activation circuit blocks 300 each activating four of the word lines WL[63:0]. The word-line activation circuit blocks 300 receive different combinations of one of the address decode signals RAD54[3:0] and one of the address decode signals RAD32[3:0]. The word-line activation circuit blocks 300 receive the inverted word-line precharge signals NPCLK[3:0] and the word-line activation signals WACTCLK[3:0].

Each of the word-line activation circuit blocks 300 includes four word-line activation circuits 301, a NAND logic device 302, an inverter 303, and four inverters 304. The NAND logic device 302 receives one of the address decode signals RAD54[3:0] and one of the address decode signals RAD32[3:0] supplied to the word-line activation circuit block 300 including this NAND logic device 302. The inverter 303 receives an output of the NAND logic device 302, and outputs an address decode signal RAD[0]-[15]. The four inverters 304 receive the inverted word-line precharge signals NPCLK[3:0], and output word-line precharge signals PCLK[3:0]. The four word-line activation circuits 301 receive the address decoder signals RAD[0]-[15] as a common signal at input terminals IN thereof, the word-line precharge signals PCLK[3:0] at input terminals PCLK thereof, and the word-line activation signals WACTCLK[3:0] at input terminals WACTCLK thereof. Then, each of the four word-line activation circuits 301 activates one of the word lines WL[63:0] from an output terminal WL thereof. The address decode signal RAD[0]-[15] is a signal that becomes active (“H” in this embodiment) when the corresponding word-line activation circuit block 300 is selected based on the address decode signals RAD54[3:0] or RAD32[3:0].

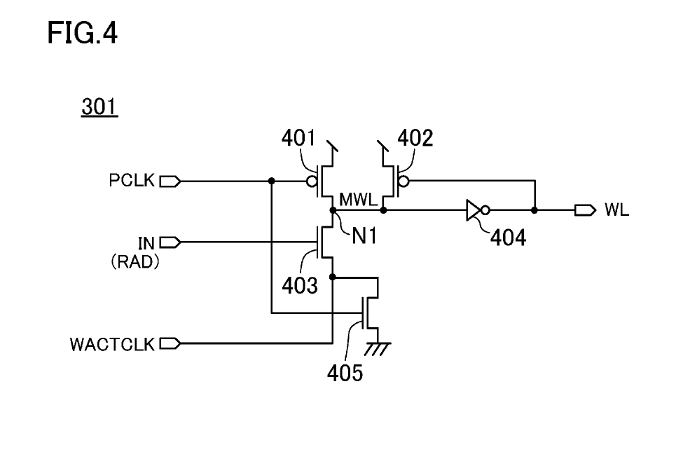

FIG. 4 illustrates a circuit configuration of the word-line activation circuit 301 of this embodiment. The circuit illustrated in FIG. 4 receives a word-line activation signal WACTCLK, an input signal IN (an address decode signal RAD) as a first input signal, and a word-line precharge signal PCLK as a second input signal, and outputs an intermediate signal (a word line signal) MWL from an output node N1. This intermediate signal MWL activates a word line WL.

An NMOS transistor 403 as a first transistor of a first conductivity type receives the word-line activation signal WACTCLK at the source thereof, has its drain coupled to the output node N1, and receives the input signal IN at the gate thereof. A PMOS transistor 401 as a second transistor of a second conductivity type has its source coupled to a first power supply that supplies a power supply voltage, has its drain coupled to the output node N1, and receives the word-line precharge signal PCLK at the gate thereof. An NMOS transistor 405 as a third transistor of the first conductivity type has its source coupled to a second power supply that supplies a ground voltage, has its drain coupled to the source of the NMOS transistor 403, and receives the word-line precharge signal PCLK at the gate thereof.

The word-line activation circuit 301 further includes a PMOS transistor 402 for holding the potential of the word line WL and an inverter 404 that receives the word line signal MWL to drive the word line WL. The PMOS transistor 402 and the inverter 404 are not necessarily provided.

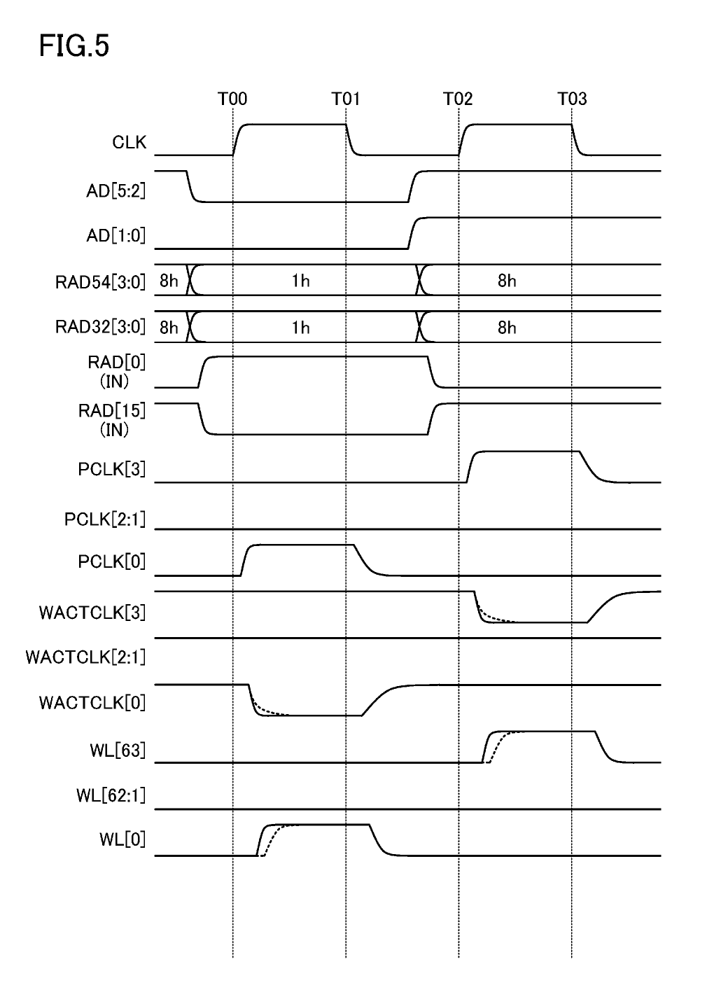

FIG. 5 is a timing chart showing signal waveforms in word-line activation in the semiconductor memory device with the circuit configuration illustrated in FIGS. 1-4. To distinguish advantages of this embodiment from those of a conventional technique, waveforms of the conventional technique are indicated by broken lines.

<Around Time T00>

Before the clock signal CLK changes to “H,” all the address signals AD[1:0] are at “L.” Since all the address signals AD[5:2] have changed from “H” to “L,” both the address decode signals RAD54[3:0] and RAD32[3:0] change from “8h” to “1h.” At this time, the address decode signal RAD[0] changes to “H,” and the input signal IN, i.e., “H,” is given to the gates of the NMOS transistors 403 in the four word-line activation circuits 301 that activate the word lines WL[3:0]. In the other word-line activation circuits 301, the NMOS transistors 403 are off.

In addition, since the clock signal CLK is at “L,” the outputs of the NAND logic devices 204 and 205 are both at “H” in each of the word-line activation signal output circuits 251 in the word-line activation signal output blocks 250. Accordingly, all the word-line precharge signals PCLK[3:0] are at “L”, and all the word-line activation signals WACTCLK[3:0] are at “H.”

At this time, in the four word-line activation circuits 301 that activate the word lines WL[3:0], the word-line activation signals WACTCLK[3:0] are at “H,” and the word-line precharge signals PCLK[3:0] are at “L” so that the PMOS transistors 401 are on. Thus, the intermediate signals MWL are at “H.” Accordingly, all the word lines WL[3:0] are at “L.” The PMOS transistors 402 turn on, and the intermediate signals MWL are kept at “H.” At this time, the NMOS transistors 405 are off.

Then, when the clock signal CLK changes to “H,” the word-line precharge signal PCLK[0] changes from “L” to “H” because all the address signals AD[1:0] are at “L.” Accordingly, in the word-line activation circuit 301 that activates the word line WL[0], the PMOS transistor 401 turns off, and the node N1 from which the intermediate signal MWL is output is coupled to the word-line activation signal WACTCLK[0] via the NMOS transistor 403. In addition, the NMOS transistor 405 turns on. At the same time, under the influence of a wiring load, the word-line activation signal WACTCLK[0] transitions from “H” to “L.”

At this time, the NMOS transistors 405 in all the word-line activation circuits 301 that receive the word-line precharge signal PCLK[0] turn on, thereby assisting discharging of the word-line activation signal WACTCLK[0] to “L.” Accordingly, the word-line activation signal WACTCLK[0] transitions to “L” at higher speed than in the conventional technique, and the intermediate signal MWL transitions to “L” at higher speed than in the conventional technique, resulting in higher-speed transition of the word line WL[0] from “L” to “H” than in the conventional technique. Since the word line WL[0] changes to “H,” the PMOS transistor 402 turns off in the word-line activation circuit 301 that activates the word line WL[0].

<Around Time T01>

When the clock signal CLK changes to “L,” the word-line precharge signal PCLK[0] changes from “H” to “L.” At this time, in the word-line activation circuit 301 that activates the word line WL[0], the PMOS transistor 401 turns on, the intermediate signal MWL is precharged to “H,” and the word line WL[0] changes to “L.” Since the word line WL[0] is at “L,” the PMOS transistor 402 turns on, and the intermediate signal MWL is kept at “H.” In addition, the NMOS transistor 405 turns off.

At the same time, although the word-line activation signal WACTCLK[0] is precharged from “L” to “H,” the NMOS transistor 405 turns off. Thus, precharging of the word-line activation signal WACTCLK[0] is not hindered.

<Around Time T02>

Since all the address signals AD[5:2] have changed from “L” to “H,” both the address decode signals RAD54[3:0] and RAD32[3:0] change from “1h” to “8h.” At this time, the address decode signal RAD[15] changes to “H,” and the input signal IN, i.e., “H,” is given to the gates of the NMOS transistors 403 in the word-line activation circuits 301 that activate the word lines WL[63:60]. In the other word-line activation circuits 301, the NMOS transistors 403 are off. All the address signals AD[1:0] have changed from “L” to “H.”

On the other hand, since the clock signal CLK is at “L,” in each of the word-line activation signal output circuits 251 in the word-line activation signal output blocks 250, the outputs of the NAND logic devices 204 and 205 are at “L.” Accordingly, all the word-line precharge signals PCLK[3:0] are at “L,” and all the word-line activation signals WACTCLK[3:0] are at “H.”

At this time, in the four word-line activation circuits 301 that activate the word lines WL[63:60], the word-line activation signals WACTCLK[3:0] are at “H,” and the word-line precharge signals PCLK[3:0] are at “L” so that the PMOS transistors 401 are on. Thus, the intermediate signals MWL are at “H.” Accordingly, the word lines WL[63:60] are at “L.” The PMOS transistors 402 turn on, and the intermediate signals MWL are kept at “H.” At this time, the NMOS transistors 405 are off.

Then, when the clock signal CLK changes to “H,” the word-line precharge signal PCLK[3] changes from “L” to “H” because all the address signals AD[1:0] are at “H.” Accordingly, in the word-line activation circuit 301 that activates the word line WL[63], the PMOS transistor 401 turns off, and the node N1 from which the intermediate signal MWL is output is coupled to the word-line activation signal WACTCLK[3] via the NMOS transistor 403. In addition, the NMOS transistor 405 turns on. At the same time, under the influence of a wiring load, the word-line activation signal WACTCK[3] transitions from “H” to “L.” At this time, the NMOS transistors 405 in all the word-line activation circuits 301 that receive the word-line precharge signal PCLK[3] turn on, thereby assisting discharging of the word-line activation signal WACTCLK[3] to “L.” Accordingly, the word-line activation signal WACTCLK[3] transitions to “L” at higher speed than in the conventional technique, and the intermediate signal MWL transitions to “L” at higher speed than in the conventional technique, resulting in higher-speed transition of the word line WL[63] from “L” to “H” than in the conventional technique. Since the word line WL[63] changes to “H,” the PMOS transistor 402 turns off in the word-line activation circuit 301 that activates the word line WL[63].

<Around Time T03>

When the clock signal CLK changes to “L,” the word-line precharge signal PCLK[3] changes from “H” to “L.” At this time, in the word-line activation circuit 301 that activates the word line WL[63], the PMOS transistor 401 turns on, the intermediate signal MWL is precharged to “H,” and the word line WL[63] changes to “L.” Since the word line WL[63] is at “L,” the PMOS transistor 402 turns on, and the intermediate signal MWL is kept at “H.” The NMOS transistor 405 turns off. At the same time, although the word-line activation signal WACTCUK[3] is precharged from “L” to “H,” the NMOS transistor 405 turns off. Thus, precharging of the word-line activation signal WACTCLK[3] is not hindered.

As described above, in this embodiment, the NMOS transistor 405 whose gate receives the word-line precharge signal PCLK is provided between the source of the NMOS transistor 403 and the power supply for the ground voltage in each of the word-line activation circuits 301. In activating the word line, this NMOS transistor 405 is caused to turn on based on the word-line precharge signal PCLK, thereby assisting discharging of the word-line activation signal WACTCLK to “L.” As a result, the word lines WL can be activated at higher speed than in conventional techniques.

Specifically, in this embodiment, in a case where a load is applied to the word-line activation signal to cause a possibility that a decrease in signal amplitude and a signal delay associated therewith occur, the word-line activation signal can be discharged to the ground voltage at high speed without a significant change in the circuit configuration and a significant increase in the circuit area. Thus, the word lines can be activated at high speed, thereby shortening an access time of the semiconductor memory device. In addition, it may be unnecessary to adjust the line width for the word-line activation signal, i.e., adjust the balance between the wiring capacitance and the wiring resistance, in order to suppress a decrease in signal amplitude.

In this embodiment, the word-line activation signal output block 250 generates, from decoded signals of the address signals AD[1:0], the inverted word-line precharge signals PCLK[3:0] respectively associated with the four word-line activation circuits 301 included in each of the word-line activation circuit blocks 300. That is, the word-line activation signal output block 250 can individually select the word-line precharge signals PCLK[3:0], and as illustrated in FIG. 5, among the word-line precharge signals PCLK[3:0], only one of the word-line precharge signals PCLK[3:0] associated with the word-line activation circuits 301 selected based on the word-line activation signals WACTCLK[3:0] is active. Thus, discharging of the word-line activation signal WACTCLK can be assisted only in the selected word-line activation circuits 301 without the influence on the non-selected word-line activation signals.

That is, in generating a plurality of word-line activation signals by decoding address signals with the configuration of this embodiment, a decrease in signal amplitude and a signal delay associated therewith can be suppressed only for the word-line activation signal selected based on the address signals without the influence on the non-selected word-line activation signals. As a result, the number of word-line activation signals can be easily increased in accordance with the address and the circuit configuration.

In addition, in this embodiment, each of the word-line activation circuits 301 has the function of assisting discharging of the word-line activation signal. Thus, even in a case where the number of word lines increases or decreases depending on the capacity of the semiconductor memory device and the load on the word-line activation signals varies, the performance of discharging the word-line activation signals changes according to the increase/decrease in the number of word lines. Thus, a signal delay can be reduced in an optimum circuit area. As a result, the capacity of the semiconductor memory device can be increased by simple calculation of the gate capacitance independently of a change in the number of word lines, without adjusting the line width of the word-line activation signals.

### Second Embodiment

The configuration of a semiconductor memory device according to a second embodiment is basically the same as that of the first embodiment illustrated in FIGS. 1-3. In this embodiment, however, the configuration of a word-line activation circuit differs from that of the first embodiment.

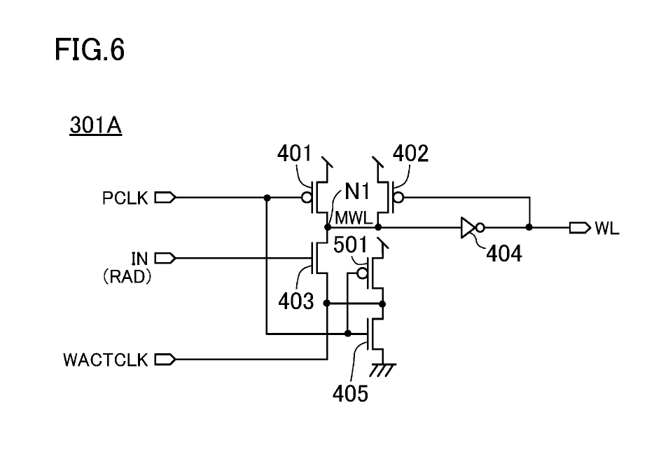

FIG. 6 illustrates a circuit configuration of a word-line activation circuit 301A according to this embodiment. The circuit configuration illustrated in FIG. 6 differs from that illustrated in FIG. 4 in that a PMOS transistor 501 is additionally provided. The PMOS transistor 501 as a fourth transistor of a second conductivity type has its source coupled to a first power supply that supplies a power supply voltage, its drain coupled to the drain of an NMOS transistor 403, and receives a word-line precharge signal PCLK at the gate thereof. That is, the PMOS transistor 501 receives a word-line activation signal WACTCLK at the drain thereof, and turns on/off based on the word-line precharge signal PCLK.

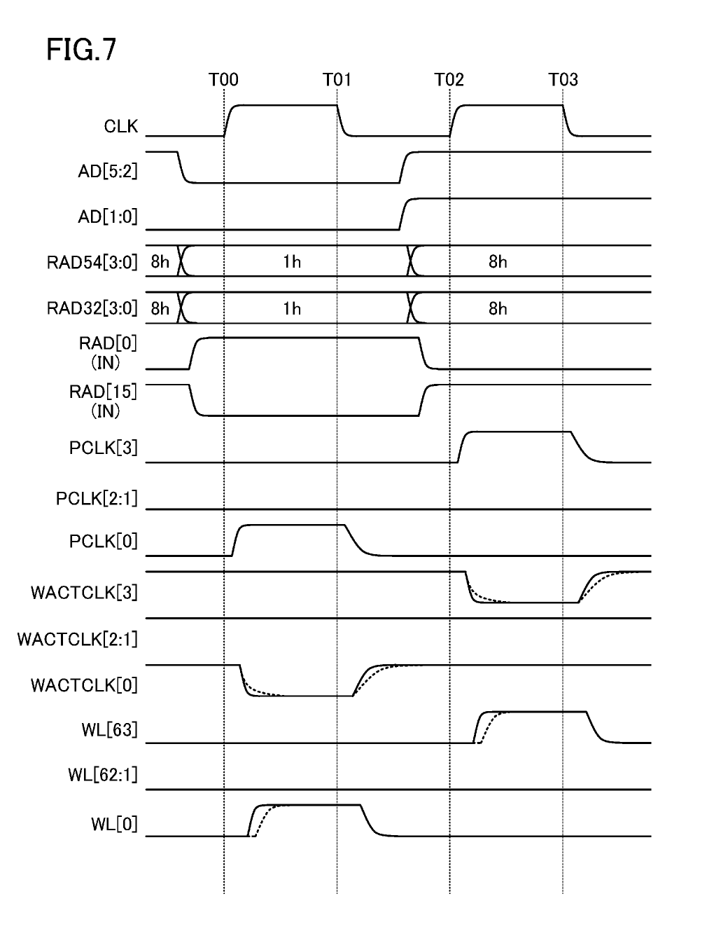

FIG. 7 shows signal waveforms in word-line activation in the semiconductor memory device with the circuit configuration illustrated in FIGS. 1-3 and 6. To distinguish advantages of this embodiment from those of a conventional technique, waveforms of the conventional technique are indicated by broken lines.

Operation illustrated in FIG. 7 is basically the same as that of the first embodiment. Thus, differences from the first embodiment will be mainly described, and description of other part of the operation is not repeated.

<Around Time T00>

When a clock signal CLK changes to “H,” a word-line precharge signal PCLK[0] changes from “L” to “H.” Thus, in the word-line activation circuit 301A that activates a word line WL[0], a PMOS transistor 401 turns off, and a node N1 from which an intermediate signal MWL is output is coupled to a word-line activation signal WACTCLK[0] via an NMOS transistor 403. In addition, an NMOS transistor 405 turns on, and the PMOS transistor 501 turns off.

At the same time, under the influence of a wiring load, the word-line activation signal WACTCLK[0] transitions from “H” to “L.” At this time, the NMOS transistors 405 in all the word-line activation circuits 301A that receive the word-line precharge signal PCLK[0] turn on, thereby assisting discharging of the word-line activation signal WACTCLK[0] to “L.”

<Around Time T01>

When the clock signal CLK changes to “L,” the word-line precharge signal PCLK[0] changes from “H” to “L.” At this time, in the word-line activation circuit 301A that activates the word line WL[0], the PMOS transistor 401 turns on, the intermediate signal MWL is precharged to “H,” and the word line WL[0] changes to “L.” Since the word line WL[0] changes to “L,” the PMOS transistor 402 turns on, and the intermediate signal MWL is kept at “H.” In addition, the NMOS transistor 405 turns off, and the PMOS transistor 501 turns on.

At the same time, under the influence of a wiring load, the word-line activation signal WACTCLK[0] is precharged from “L” to “H.” At this time, since the PMOS transistor 501 is on, precharging of the word-line activation signal WACTCLK[0] to “H” is assisted, thereby completing precharging of the word-line activation signal WACTCLK[0] at higher speed than in the conventional technique. In addition, since the NMOS transistor 405 is off, precharging of the word-line activation signal WACTCLK[0] is not hindered.

<Around time T02>

When the clock signal CLK changes to “H,” a word-line precharge signal PCLK[3] changes from “L” to “H.” Thus, in the word-line activation circuit 301A that activates a word line WL[63], the PMOS transistor 401 turns off, and the node N1 from which the intermediate signal MWL is output is coupled to a word-line activation signal WACTCLK[3] via the NMOS transistor 403. In addition, the NMOS transistor 405 turns on, and the PMOS transistor 501 turns on.

At the same time, under the influence of a wiring load, the word-line activation signal WACTCK[3] transitions from “H” to “L.” At this time, the NMOS transistors 405 in all the word-line activation circuits 301A that receive the word-line precharge signal PCLK[3] turn on, thereby assisting discharging of the word-line activation signal WACTCLK[3] to “L.”

<Around Time T03>

When the clock signal CLK changes to “L,” the word-line precharge signal PCLK[3] changes from “H” to “L.” At this time, in the word-line activation circuit 301A that activates the word line WL[63], the PMOS transistor 401 turns on, the intermediate signal MWL is precharged to “H,” and the word line WL[63] changes to “L.” Since the word line WL[63] changes to “L,” the PMOS transistor 402 turns on, and the intermediate signal MWL is kept at “H.” In addition, the NMOS transistor 405 turns off, and the PMOS transistor 501 turns on.

At the same time, under the influence of a wiring load, the word-line activation signal WACTCLK[3] is precharged from “L” to “H.” At this time, since the PMOS transistor 501 is on, precharging of the word-line activation signal WACTCLK[3] to “H” is assisted, thereby completing precharging of the word-line activation signal WACTCLK[3] at higher speed than in the conventional technique. In addition, since the NMOS transistor 405 is off, precharging of the word-line activation signal WACTCLK[3] is not hindered.

As described above, in this embodiment, the PMOS transistor 501 that receives the word-line precharge signal PCLK at the gate thereof is provided between the source of the NMOS transistor 403 and the power supply for the power supply voltage in each of the word-line activation circuits 301A. In precharging the word line, the PMOS transistor 501 turns on based on the word-line precharge signal PCLK, thereby assisting precharging of the word-line activation signal WACTCLK to “H.” As a result, the word-line activation signal WACTCLK can be precharged at higher speed than in conventional techniques.

Similarly to the first embodiment, the NMOS transistor 405 that receives the word-line precharge signal PCLK at the gate thereof is provided between the source of the NMOS transistor 403 and the power supply for the ground voltage. Thus, in activating the word line, the NMOS transistor 405 can assist discharging of the word-line activation signal WACTCLK to “L.” As a result, the word lines WL can be activated at higher speed than in conventional techniques.

That is, in this embodiment, even in a case where a load is applied to a word-line activation signal to cause a possibility that a decrease in signal amplitude and a signal delay associated therewith occur, the word-line activation signal can be discharged to the ground voltage at high speed without a significant change in the circuit configuration and a significant increase in the circuit area, and can also be precharged to the power supply voltage at high speed. Thus, the access time of the semiconductor memory device can be shortened, and the cycle time can be reduced. In addition, it may be unnecessary to adjust the line width for the word-line activation signal, i.e., adjust the balance between the wiring capacity and the wiring resistance, in order to suppress a decrease in signal amplitude. Moreover, the size of a buffer for driving the word-line activation signal can be reduced, thereby enabling reduction of the circuit area.

In this embodiment, the word-line activation signal output block 250 generates, from decoded signals of address signals AD[1:0], the word-line activation signals WACTCLK[3:0] and the inverted word-line precharge signals PCLK[3:0] respectively associated with the four word-line activation circuits 301A included in each word-line activation circuit block 300. That is, the word-line activation signal output block 250 can individually select the word-line precharge signals PCLK[3:0], and as illustrated in FIG. 7, among the word-line precharge signals PCLK[3:0], only one of the word-line precharge signals PCLK[3:0] associated with the word-line activation circuits 301A selected based on the word-line activation signals WACTCLK[3:0] is active. Thus, discharging of the word-line activation signal WACTCLK can be assisted only in the selected word-line activation circuits 301A without the influence on the non-selected word-line activation signals.

That is, in generating a plurality of word-line activation signals by decoding address signals with the configuration of this embodiment, a decrease in signal amplitude and a signal delay associated therewith can be suppressed only for the word-line activation signal selected based on the address signals without the influence on the non-selected word-line activation signals. As a result, the number of word-line activation signals can be easily increased in accordance with the address and the circuit configuration.

In addition, in this embodiment, each of the word-line activation circuits 301A has the function of assisting discharging and precharging of the word-line activation signal. Thus, even in a case where the number of word lines increases or decreases depending on the capacity of the semiconductor memory device and the load on the word-line activation signals varies, the performance of discharging and precharging the word-line activation signals changes according to the increase/decrease in the number of word lines. Thus, a signal delay can be reduced in an optimum circuit area. As a result, the capacity of the semiconductor memory device can be increased by simple calculation of the gate capacitance independently of a change in the number of word lines, without adjusting the line width of the word-line activation signals.

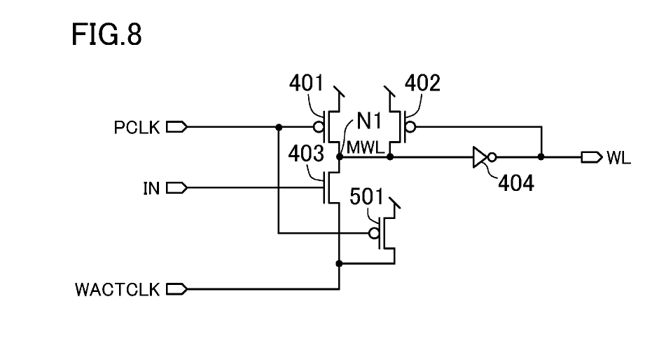

As illustrated in FIG. 8, the NMOS transistor 405 may be omitted in FIG. 6. This circuit configuration illustrated in FIG. 8 can also assist precharging of the word-line activation signal WACTCLK to “H,” and thus, the word-line activation signal WACTCLK can be precharged at higher speed than in conventional techniques.

### Third Embodiment

The configuration of a semiconductor memory device according to a third embodiment is basically the same as that of the first embodiment except for the configurations of word-line activation signal output circuits in the row decoder control circuit and the word-line activation circuits.

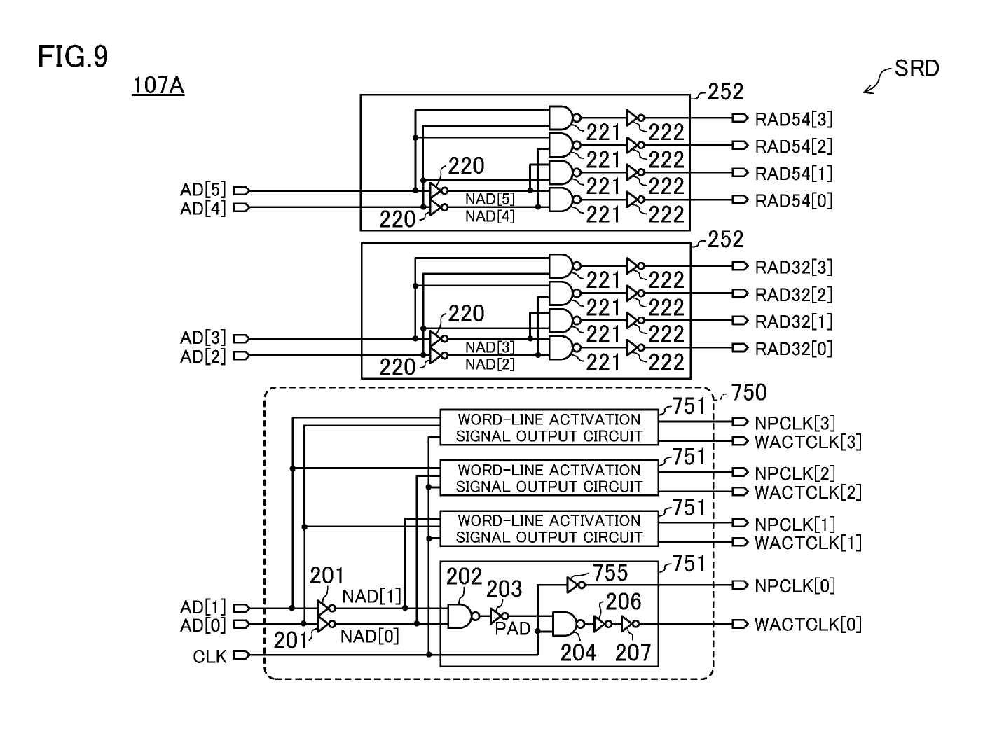

FIG. 9 illustrates a circuit configuration of a row decoder control circuit 107A according to this embodiment. The row decoder control circuit 107A illustrated in FIG. 9 includes a word-line activation signal output block 750 and two address decoders 252, and generates, as row decoder control signals SRD, address decode signals RAD32[3:0] and RAD54[3:0], inverted word-line precharge signals NPCLK[3:0] for precharging the potentials of word lines, and word-line activation signals WACTCLK[3:0] for controlling activation timings of the word lines. The configuration of the address decoders 252 is basically the same as that illustrated in FIG. 2, and description thereof is not repeated.

The word-line activation signal output block 750 includes two inverters 201 and four word-line activation signal output circuits 751, receives address signals AD[1:0] and a clock signal CLK, and outputs word-line activation signals WACTCLK[3:0] and inverted word-line precharge signals NPCLK[3:0]. Instead of the word-line activation signals WACTCLK, inverted signals thereof may be output. Instead of the inverted word-line precharge signals NPCLK, word-line precharge signals PCLK[3:0] may be output. Each of the word-line activation signal output circuits 751 includes NAND logic devices 202 and 204 and inverters 203, 206, 207, and 755.

The two inverters 201 receive address signals AD[1] and AD[0], and output inverted address signals NAD[1] and NAD[0]. The four word-line activation signal output circuits 751 receive the clock signal CLK and different combinations of one of the address signal AD[1] or the inverted address signal NAD[1] and one of the address signal AD[0] or the inverted address signal NAD[0]. The four word-line activation signal output circuits 751 outputs the word-line activation signals WACTCLK[3:0] and the inverted word-line precharge signals NPCLK[3:0].

In each of the word-line activation signal output circuits 751, the NAND logic device 202 receives one of the address signal AD[1] or the inverted address signal NAD[1] and one of the address signal AD[0] or the inverted address signal NAD[0]. The inverter 203 receives an output of the NAND logic device 202, and outputs an inverted signal thereof as an address decode signal PAD. The NAND logic device 204 receives the clock signal CLK and the address decode signal PAD, and outputs a signal through the inverters 206 and 207 as one of the word-line activation signals WACTCLK[3:0]. The inverter 755 receives the clock signal CLK, and output an inverted signal thereof as one of the inverted word-line precharge signals NPCLK[3:0].

That is, the row decoder control circuit 107A illustrated in FIG. 9 outputs, as the inverted word-line precharge signals NPCLK[3:0], the same signal, i.e., the inverted signal of the clock signal CLK. In FIG. 9, the inverted word-line precharge signals NPCLK[3:0] are four individual signals. Alternatively, the inverted word-line precharge signals NPCLK[3:0] may be a common signal to be input to all the word-line activation circuits.

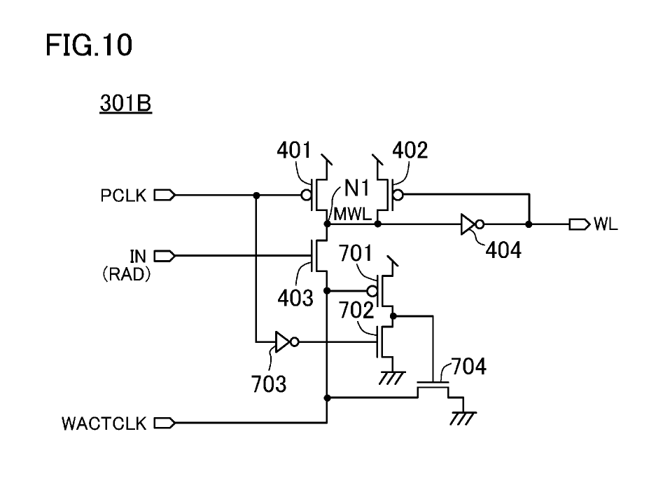

FIG. 10 illustrates a circuit configuration of a word-line activation circuit 301B according to this embodiment. Similarly to the circuit illustrated in FIG. 4, the circuit illustrated in FIG. 10 receives the word-line activation signal WACTCLK, an input signal IN as a first input signal, and a word-line precharge signal PCLK as a second input signal, and outputs an intermediate signal (a word line signal) MWL from an output node N1. This intermediate signal MWL activates a word line WL.

An NMOS transistor 403 as a first transistor of a first conductivity type receives the word-line activation signal WACTCLK at the source thereof, has its drain coupled to the output node N1, and receives an input signal IN at the gate thereof. A PMOS transistor 401 as a second transistor of a second conductivity type has its source coupled to a first power supply that supplies a power supply voltage, has its drain coupled to the output node N1, and receives the word-line precharge signal PCLK at the gate thereof. An NMOS transistor 704 as a third transistor of the first conductivity type has its source coupled to a second power supply that supplies a ground voltage and has its drain coupled to the source of the NMOS transistor 403. A PMOS transistor 701 as a fourth transistor of the second conductivity type has its source coupled to the first power supply, has its drain coupled to the gate of the NMOS transistor 704, and has its gate coupled to the source of the NMOS transistor 403. The PMOS transistor 701 turns on and off based on the word-line activation signal WACTCLK.

The inverter 703 receives the word-line precharge signal PCLK, and outputs an inverted signal thereof. An NMOS transistor 702 as a fifth transistor of the first conductivity type has its source coupled to the second power supply that supplies the ground voltage, has its drain coupled to the drain of the PMOS transistor 701, and receives an inverted signal output from the inverter 703 at the gate thereof. The inverter 703 and the NMOS transistor 702 are not necessarily provided.

The word-line activation circuit 301B further includes a PMOS transistor 402 for holding the potential of the word line WL and an inverter 404 that receives the word line signal MWL to drive the word line WL. The PMOS transistor 402 and the inverter 404 are not necessarily provided.

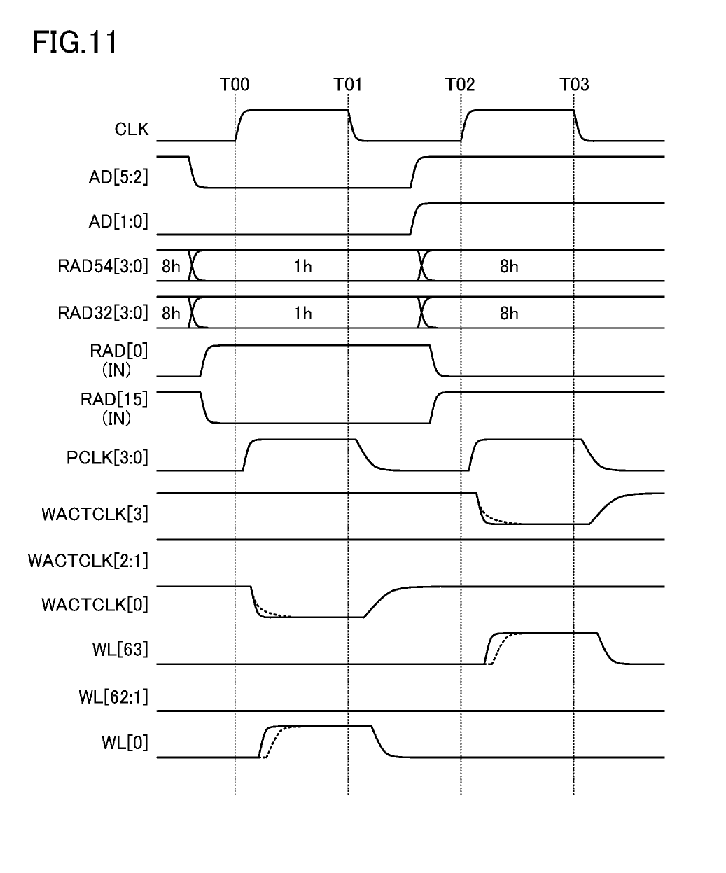

FIG. 11 is a timing chart showing signal waveforms in word-line activation in the semiconductor memory device with the circuit configuration illustrated in FIGS. 1, 3, 9, and 10. To distinguish advantages of this embodiment from those of a conventional technique, waveforms of the conventional technique are indicated by broken lines.

<Around Time T00>

Before the clock signal CLK changes to “H,” all the address signals AD[1:0] are at “L.” Since all the address signals AD[5:2] have changed from “H” to “L,” both the address decode signals RAD54[3:0] and RAD32[3:0] change from “8h” to “1h.” At this time, the address decode signal RAD[0] changes to “H,” and an input signal IN, i.e., “H,” is given to the gates of the NMOS transistors 403 in the four word-line activation circuits 301B that activate the word lines WL[3:0]. In the other word-line activation circuits 301B, the NMOS transistors 403 are off.

In addition, since the clock signal CLK is at “L,” the outputs of the NAND logic device 204 and the inverter 755 are both at “H” in each of the word-line activation signal output blocks 751 in the word-line activation signal output blocks 750. Accordingly, all the word-line precharge signals PCLK[3:0] are at “L”, and all the word-line activation signals WACTCLK[3:0] are at “H.”

At this time, in the four word-line activation circuits 301B that activate the word lines WL[3:0], the word-line activation signals WACTCLK[3:0] are at “H,” and the word-line precharge signals PCLK[3:0] are at “L” so that the PMOS transistors 401 are on. Thus, the intermediate signals MWL are at “H.” Accordingly, all the word lines WL[3:0] are at “L.” The PMOS transistors 402 turn on, and the intermediate signals MWL are kept at “H.” At this time, the PMOS transistors 701 are off, and the NMOS transistors 702 are on. Thus, “L” is supplied to the gates of the NMOS transistors 704, and the NMOS transistors 704 are off.

Then, when the clock signal CLK changes to “H,” the word-line precharge signals PCLK[3:0] change from “L” to “H”. Accordingly, in the word-line activation circuits 301B that activate the word lines WL[3:0], the PMOS transistors 401 and the NMOS transistors 702 turn off. In the word-line activation circuit 301B that activates the word line WL[0], the node N1 from which the intermediate signal MWL is output is coupled to the word-line activation signal WACTCLK[0] via the NMOS transistor 403.

At the same time, under the influence of a wiring load, the word-line activation signal WACTCLK[0] transitions from “H” to “L.” At this time, when the potential of the word-line activation signal WACTCLK[0] decreases to a level at which the PMOS transistor 701 turns on, the PMOS transistor 701 turns on, and “H” is given to the gate of the NMOS transistor 704, thereby causing the NMOS transistor 704 to turn on. That is, the NMOS transistors 704 in all the word-line activation circuits 301B that receive the word-line activation signal WACTCLK[0] turn on, thereby assisting discharging of the word-line activation signal WACTCLK[0] to “L.” Accordingly, the word-line activation signal WACTCLK[0] transitions to “L” at higher speed than in the conventional technique, and the intermediate signal MWL transitions to “L” at higher speed than in the conventional technique, resulting in higher-speed transition of the word line WL[0] from “L” to “H” than in the conventional technique. Since the word line WL[0] changes to “H,” the PMOS transistor 402 turns off in the word-line activation circuit 301B that activates the word line WL[0].

<Around Time T01>

When the clock signal CLK changes to “L,” the word-line precharge signals PCLK[3:0] change from “H” to “L.” At this time, in the word-line activation circuits 301B that activate the word lines WL[3:0], the NMOS transistors 702 turn on and the PMOS transistors 401 turn on, so that the intermediate signal MWL is precharged to “H” and the word line WL[0] changes to “L.” Since the word line WL[0] is at “L,” the PMOS transistor 402 turns on, and the intermediate signal MWL is kept at “H.”

At the same time, when the word-line activation signal WACTCLK[0] is precharged from “L” to “H” and the PMOS transistor 701 turns off, the NMOS transistor 704 turns off because the NMOS transistor 702 is on. Thus, the NMOS transistor 704 does not hinder precharging of the word-line activation signal WACTCLK[0].

<Around Time T02>

Since all the address signals AD[5:2] have changed from “L” to “H,” both the address decode signals RAD54[3:0] and RAD32[3:0] change from “1h” to “8h.” At this time, the address decode signal RAM[15] changes to “H,” and an input signal IN, i.e., “H,” is given to the gates of the NMOS transistors 403 in the word-line activation circuits 301B that activate the word lines WL[63:60]. In the other word-line activation circuits 301B, the NMOS transistors 403 are off. All the address signals AD[1:0] have changed from “L” to “H.”

On the other hand, since the clock signal CLK is at “L,” in each of the word-line activation signal output circuits 751 in the word-line activation signal output blocks 750, the outputs of the NAND logic device 204 and the inverter 755 are at “H.” Accordingly, all the word-line precharge signals PCLK[3:0] are at “L,” and all the word-line activation signals WACTCLK[3:0] are at “H.”

At this time, in all the four word-line activation circuits 301B that activate the word lines WL[63:60], the word-line activation signals WACTCLK[3:0] are at “H,” and the word-line precharge signals PCLK[3:0] are at “L” so that the PMOS transistors 401 are on. Thus, the intermediate signals MWL are at “H.” Accordingly, all the word lines WL[63:60] are at “L.” The PMOS transistors 402 turn on, and the intermediate signals MWL are kept at “H.” At this time, the PMOS transistors 701 are off, and the NMOS transistors 702 are on. Thus, “L” is supplied to the gates of the NMOS transistors 704, and the NMOS transistors 704 are off.

Then, when the clock signal CLK changes to “H,” the word-line precharge signals PCLK[3:0] change from “L” to “H.” Accordingly, in the word-line activation circuits 301B that activate the word lines WL[63:60], the PMOS transistors 401 and the NMOS transistors 702 turn off. In the word-line activation circuit 301B that activates the word line WL[63], the node N1 from which the intermediate signal MWL is output is coupled to the word-line activation signal WACTCLK[3] via the NMOS transistor 403.

At the same time, under the influence of a wiring load, the word-line activation signal WACTCK[3] transitions from “H” to “L.” At this time, when the potential of the word-line activation signal WACTCLK[3] decreases to a level at which the PMOS transistor 701 turns on, the PMOS transistor 701 turns on, and “H” is given to the gate of the NMOS transistor 704, thereby causing the NMOS transistor 704 to turn on. That is, the NMOS transistors 704 in all the word-line activation circuits 301B that receive the word-line activation signal WACTCLK[3] turn on, thereby assisting discharging of the word-line activation signal WACTCLK[3] to “L.” Accordingly, the word-line activation signal WACTCLK[3] transitions to “L” at higher speed than in the conventional technique, and the intermediate signal MWL transitions to “L” at higher speed than in the conventional technique, resulting in higher-speed transition of the word line WL[63] from “L” to “H” than in the conventional technique. Since the word line WL[63] changes to “H,” the PMOS transistor 402 turns off in the word-line activation circuit 301B that activates the word line WL[63].

<Around Time T03>

When the clock signal CLK changes to “L,” the word-line precharge signals PCLK[3:0] change from “H” to “L.” At this time, in the word-line activation circuits 301B that activate the word lines WL[63:60], the NMOS transistors 702 turn on and the PMOS transistors 401 turn on, so that the intermediate signals MWL is precharged to “H” and the word line WL[63] changes to “L.” Since the word line WL[63] is at “L,” the PMOS transistor 402 turns on, and the intermediate signal MWL is kept at “H.”

At the same time, when the word-line activation signal WACTCLK[3] is precharged from “L” to “H” and the PMOS transistor 701 turns off, the NMOS transistor 704 turns off because the NMOS transistor 702 is on. Thus, the NMOS transistor 704 does not hinder precharging of the word-line activation signal WACTCLK[3].

As described above, in this embodiment, the NMOS transistor 704 is provided between the source of the NMOS transistor 403 and the power supply for the ground voltage in each of the word-line activation circuits 301B. Turning on and off of this NMOS transistor 704 is controlled based on the word-line precharge signal PCLK and the word-line activation signal WACTCLK. In this manner, in activating the word line, the NMOS transistor 704 can assist discharging of the word-line activation signal WACTCLK to “L.” As a result, the word lines WL can be activated at higher speed than in conventional techniques.

That is, in this embodiment, even in a case where a load is applied to a word-line activation signal to cause a possibility that a decrease in signal amplitude and a signal delay associated therewith occur, the word-line activation signal can be discharged at high speed without a significant change in the circuit configuration and a significant increase in the circuit area. Thus, the word lines can be activated at high speed, and the access time of the semiconductor memory device can be shortened. In addition, it may be unnecessary to adjust the line width for the word-line activation signal, i.e., adjust the balance between the wiring capacitance and the wiring resistance, in order to suppress a decrease in signal amplitude.

In the foregoing embodiments, the input signal IN changes earlier than the word-line precharge signal PCLK as an example of signal waveforms. Alternatively, the input signal IN and the word-line precharge signal PCLK may change at the same time. Preferably, the input signal IN is established before the word-line activation signal WACTCLK changes from “H” to “L” and before the word-line precharge signal PCLK changes from “L” to “H.”

The word-line activation circuit of each of the foregoing embodiments receives, as input signal except the word-line activation signal WACTCLK, two input signals, e.g., the input signal IN and the word-line precharge signal PCLK. Alternatively, these two input signals may be a common signal.

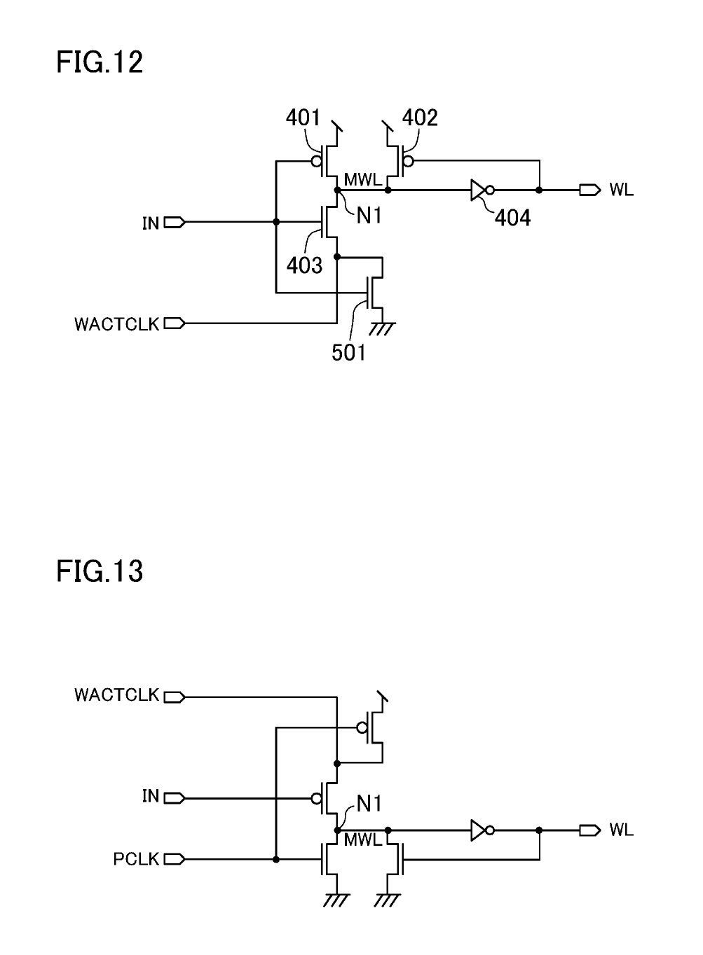

For example, FIG. 12 illustrates a variation of the word-line activation circuit 301 illustrated in FIG. 4. In FIG. 12, no word-line precharge signal PCLK is input, and the input signal IN is commonly input to the gates of the PMOS transistor 401, the NMOS transistor 403, and the NMOS transistor 501. The word-line activation circuit 301A illustrated in FIG. 6 and the word-line activation circuit 301B illustrated in FIG. 10 may also be modified in the same manner as the word-line activation circuit illustrated in FIG. 12.

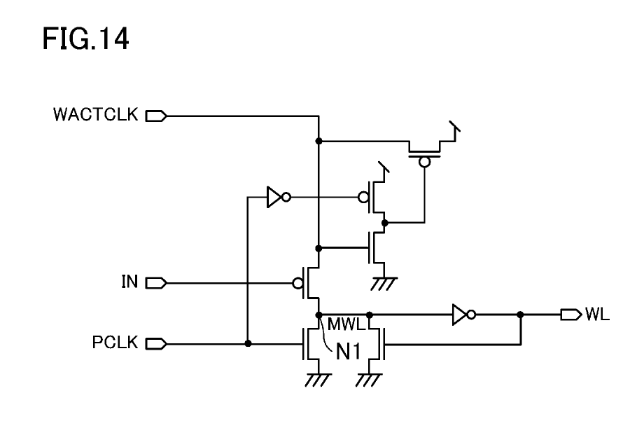

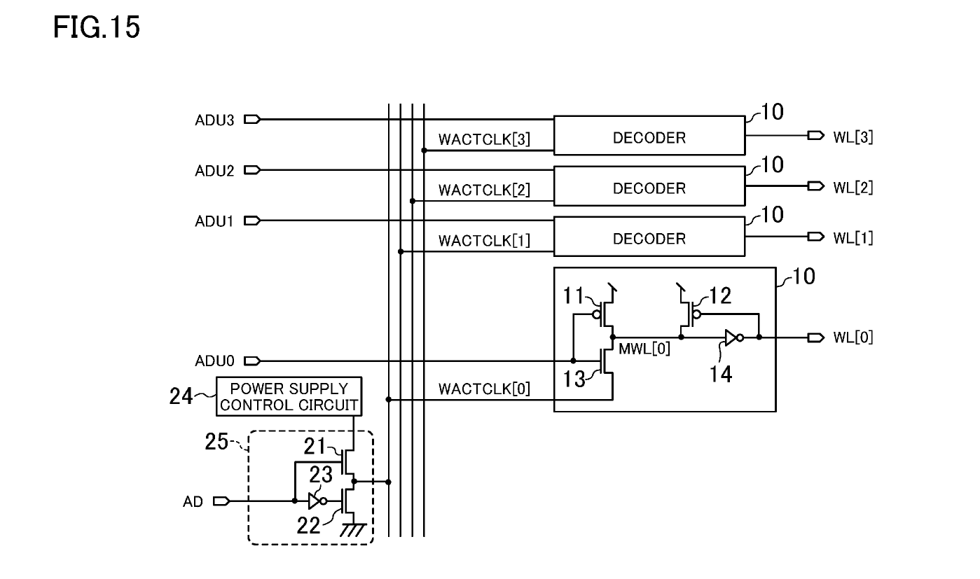

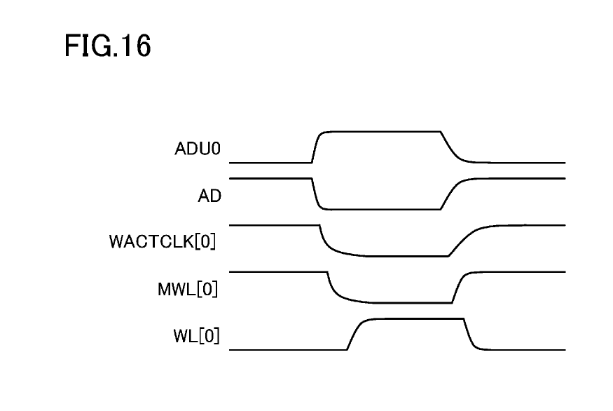

In the word-line activation circuits of the foregoing embodiments, the PMOS transistors and the NMOS transistors may be replaced with each other, and the power supply for the power supply voltage and the power supply for the ground voltage may be replaced with each other. In this case, advantages similar to those of the foregoing embodiments can be obtained. For example, FIG. 13 illustrates a circuit configuration obtained by modifying the word-line activation circuit 301 illustrated in FIG. 4 such that the PMOS transistors are replaced with the NMOS transistors and the power supply for the power supply voltage is replaced with the power supply for the ground voltage. FIG. 14 illustrates a circuit configuration obtained by modifying the word-line activation circuit 301B illustrated in FIG. 10 such that the PMOS transistors are replaced with the NMOS transistors and the power supply voltage for the power supply voltage is replaced with the power supply for the ground voltage. In this case, the logic of active/inactive of each signal is inverted from that of the foregoing embodiments.

In the word-line activation circuits of the foregoing embodiments, each transistor may be a combination of a plurality of transistors. For example, in the word-line activation circuit 301 illustrated in FIG. 4, the transistor 405 may include a plurality of transistors that are connected together in series or in parallel, or in combination of serial and parallel connections, between the second power supply and the source of the transistor 403 and receive the word-line precharge signals PCLK at the gates thereof. Alternatively, in the word-line activation circuit 301B illustrated in FIG. 10, the transistor 704 may be made of a plurality of transistors that are connected together in series or in parallel, or in combination of serial and parallel connections, between the second power supply and the source of the transistor 403 and have their gates coupled to the drain of the transistor 701.

In the foregoing embodiments, the address signal AD is of six bits for simplicity of explanation. However, the present disclosure is not limited to this example as long as the word lines WL can be selected based on the address decode signal RAD. Similarly, the numbers of the word lines WL, the bit lines BL, and the pieces of output data DO are not limited to those described above. In addition to the bit lines BL connected to the memory array 103, bit lines NBL having the inverted logic may be connected to the memory array 103.

In the foregoing embodiments, each of the address decoders 252 has the circuit configuration that generates the 4-bit address decode signal RAD from the 2-bit address signal AD. However, the circuit configuration of the address decoders, the number of input address signals, and the number of the output address decode signals are not limited to those described above. The number of the address decoders 252 is two in the foregoing embodiments, but may be one or three or more. That is, the number of the address decoders 252 only needs to be increased or reduced in accordance with the address signal AD to be input.

In the foregoing embodiments, the word-line activation signal output blocks 250 and 750 receive two bits of AD[1:0] as part of the address signal AD. Alternatively, the number of bits of the address signal AD input to the word-line activation signal output blocks 250 and 750 is not limited to this example.

In the foregoing embodiments, the semiconductor memory devices have the configuration in which the word-line activation circuits activate the word lines at high speed. However, the circuit configurations of the word-line activation circuits of the foregoing embodiments are not limited to the use for driving the word lines as described above, and may be applied to other uses. Specifically, the above-described circuit configurations may be applied to a semiconductor integrated circuit in which when a pulse drive signal WACTCLK becomes active, a pulse signal MWL for, for example, controlling circuits at subsequent stages is output from an output node N1. In this case, the pulse signal MWL can rise at high speed. Accordingly, the activation speed of circuits at subsequent stages can be increased, for example.

According to the present disclosure, word lines can be activated at higher speed independently of the type and configuration of a semiconductor memory device. Thus, the present disclosure is useful for the fields requiring shortening of the access time of data output or requiring both increase in capacity and shortening of the access time and the fields requiring shortening of the cycle time of data output or requiring both increase in capacity and shortening of the cycle time of data output.

What is claimed is:

1. A word-line activation circuit, comprising:
an output node configured to output a word line signal;
a first transistor of a first conductivity type configured to receive a word-line activation signal at a source thereof, have its drain coupled to the output node, and receive a first input signal at a gate thereof;
a second transistor of a second conductivity type configured to have its source coupled to a first power supply, have its drain coupled to the output node, and receive a second input signal at a gate thereof; and
a third transistor of the first conductivity type configured to have its source coupled to a second power supply, have its drain coupled to the source of the first transistor, and receive the second input signal at a gate thereof.

2. The word-line activation circuit of claim 1, further comprising
a fourth transistor of the second conductivity type configured to have its source coupled to the first power supply, have its drain coupled to the drain of the third transistor, and receive the second input signal at a gate thereof.

3. The word-line activation circuit of claim 1, wherein
the third transistor comprises a plurality of transistors that are connected together in series or in parallel, or in combination of serial and parallel connections, between the second power supply and the source of the first transistor and receive the second input signal at gates thereof.

4. A word-line activation circuit, comprising:
an output node configured to output a word line signal;
a first transistor of a first conductivity type configured to receive a word-line activation signal at a source thereof, have its drain coupled to the output node, and receive a first input signal at a gate thereof;
a second transistor of a second conductivity type configured to have its source coupled to a first power supply, have its drain coupled to the output node, and receive a second input signal at a gate thereof;
a third transistor of the first conductivity type configured to have its source coupled to a second power supply and have its drain coupled to the source of the first transistor; and
a fourth transistor of the second conductivity type configured to have its source coupled to the first power supply, have its drain coupled to the gate of the third transistor, and have its gate coupled to the source of the first transistor.

5. The word-line activation circuit of claim 4, further comprising:
an inverter configured to receive the second input signal and output an inverted signal of the second input signal; and
a fifth transistor of the first conductivity type configured to have its source coupled to the second power supply, have its drain coupled to the drain of the fourth transistor, and receive the inverted signal at a gate thereof.

6. The word-line activation circuit of claim 4, wherein
the third transistor comprises a plurality of transistors that are connected together in series or in parallel, or in combination of serial and parallel connections, between the second power supply and the source of the first transistor and have their gates coupled to the gate of the third transistor.

7. The word-line activation circuit of claim 1, wherein
a common signal is input as the first and second input signals.

8. The word-line activation circuit of claim 1, wherein
the first conductivity type is an n-type,
the second conductivity type is a p-type,
the first power supply supplies a power supply voltage, and
the second power supply supplies a ground voltage.

9. The word-line activation circuit of claim 1, wherein
the first conductivity type is a p-type,
the second conductivity type is an n-type,
the first power supply supplies a ground voltage, and
the second power supply supplies a power supply voltage.

10. A word-line activation circuit, comprising:
an output node configured to output a word line signal;
a first transistor of a first conductivity type configured to receive a word-line activation signal at a source thereof, have its drain coupled to the output node, and receive a first input signal at a gate thereof;
a second transistor of a second conductivity type configured to have its source coupled to a first power supply, have its drain coupled to the output node, and receive a second input signal at a gate thereof; and
a third transistor of the second conductivity type configured to have its source coupled to the first power supply, have its drain coupled to the source of the first transistor, and receive the second input signal at a gate thereof.

11. A semiconductor memory device, comprising:
a word-line activation circuit block including a predetermined number of the word-line activation circuits of claim 1; and
a word-line activation signal output block configured to receive a part of an address signal and a clock signal for controlling a word-line activation timing, generate and output, to each of the predetermined number of word-line activation circuits, either the word-line activation signal or an inverted signal of the word-line activation signal and either the second input signal or an inverted signal of the second input signal.

12. The semiconductor memory device of claim 11, wherein
the word-line activation circuit block comprises a plurality of word-line activation circuit blocks,
the semiconductor memory device further includes at least one address decoder configured to receive a remain other than the part of the address signal and generate an address decode signal for selecting one of the word-line activation circuit blocks, and
each of the word-line activation circuit blocks is configured such that the predetermined number of word-line activation circuit blocks receive a common signal as the first input signal, and when one of the word-line activation circuit blocks is selected based on the address decode signal, the first input signal to be input to the selected word-line activation circuit block becomes active.

13. A semiconductor integrated circuit, comprising:
an output node configured to output a pulse signal;
a first transistor of a first conductivity type configured to receive a pulse activation signal at a source thereof, have its drain coupled to the output node, and receive a first input signal at a gate thereof;
a second transistor of a second conductivity type configured to have its source coupled to a first power supply, have its drain coupled to the output node, and receive a second input signal at a gate thereof; and
a third transistor of the first conductivity type configured to have its source coupled to a second power supply, have its drain coupled to the source of the first transistor, and receive the second input signal at a gate thereof.

14. A semiconductor integrated circuit, comprising:
an output node configured to output a pulse signal;
a first transistor of a first conductivity type configured to receive a pulse activation signal at a source thereof, have its drain coupled to the output node, and receive a first input signal at a gate thereof;
a second transistor of a second conductivity type configured to have its source coupled to a first power supply, have its drain coupled to the output node, and receive a second input signal at a gate thereof; and
a third transistor of the first conductivity type configured to have its source coupled to a second power supply and have its drain coupled to the source of the first transistor; and
a fourth transistor of the second conductivity type configured to have its source coupled to the first power supply, have its drain coupled to the gate of the third transistor, and have its gate coupled to the source of the first transistor.

15. The word-line activation circuit of claim 4, wherein
a common signal is input as the first and second input signals.

16. The word-line activation circuit of claim 4, wherein
the first conductivity type is an n-type,
the second conductivity type is a p-type,
the first power supply supplies a power supply voltage, and
the second power supply supplies a ground voltage.

17. The word-line activation circuit of claim 4, wherein
the first conductivity type is a p-type,
the second conductivity type is an n-type,
the first power supply supplies a ground voltage, and
the second power supply supplies a power supply voltage.

18. A semiconductor memory device, comprising:
a word-line activation circuit block including a predetermined number of the word-line activation circuits of claim 4; and
a word-line activation signal output block configured to receive a part of an address signal and a clock signal for controlling a word-line activation timing, generate and output, to each of the predetermined number of word-line activation circuits, either the word-line activation signal or an inverted signal of the word-line activation signal and either the second input signal or an inverted signal of the second input signal.

19. The semiconductor memory device of claim 18, wherein
the word-line activation circuit block comprises a plurality of word-line activation circuit blocks,
the semiconductor memory device further includes at least one address decoder configured to receive a remain other than the part of the address signal and generate an address decode signal for selecting one of the word-line activation circuit blocks, and
each of the word-line activation circuit blocks is configured such that the predetermined number of word-line activation circuit blocks receive a common signal as the first input signal, and when one of the word-line activation circuit blocks is selected based on the address decode signal, the first input signal to be input to the selected word-line activation circuit block becomes active.
